(19) United States
(12) Patent Application Publication
(10) Pub. No.: US 2026/0198251 A1
(43) Pub. Date: Jul. 9, 2026

(54) PEDESTAL WITH SPIRAL VANES

(71) Applicant: Lam Research Corporation, Fremont, CA (US)

(72) Inventors: Ujjwal Aashray Trakroo, Jammu (IN); Narudha Tai Ben-Yuhmin, Santa Clara, CA (US); Jeffrey Michael Chalmers, Newark, CA (US); Jerome S. Hubacek, Fremont, CA (US); Seyedalireza Torbatisarraf, San Jose, CA (US); Yogesh Mahesh Sovani, Ichalkaranji (IN); Conor Le Gear, Amsterdam (NL)

(21) Appl. No.: 19/134,212

(22) PCT Filed: Nov. 29, 2023
(86) PCT No.: PCT/US2023/081694

§ 371 Date: May 30, 2025

Related U.S. Application Data
(60) Provisional application No. 63/385,563, filed on Nov. 30, 2022.

(51) Int. Cl. H10P 72/00; H10P 72/72

(52) U.S. Cl. CPC H10P 72/0434; H10P 72/722

(57) ABSTRACT

This disclosure pertains to pedestal assemblies for supporting wafers in semiconductor manufacturing tools and chambers. Such pedestal assemblies may have a pedestal base that is configured with an internal plenum volume having a plurality of vanes distributed throughout along various spiral reference paths. Such pedestal bases may provide enhanced and more uniform cooling.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor processing tools typically require the supply of different reactant gases to wafer processing spaces located within one or more semiconductor processing chambers. Semiconductor wafers processed in such chambers are typically supported on a pedestal, e.g., a platform that may have a chuck or other system for immobilizing the wafer in place on a wafer support surface thereof, during processing operations.

Discussed herein are various improvements to pedestals for use in some semiconductor processing systems.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus for use in semiconductor processing operations may be provided. The apparatus may include a pedestal base having a first side and a second side. The pedestal base may include a first internal plenum volume radiating outward from a center axis, located between the first side and the second side, at least partially bounded on one side by a first surface and at least partially bounded on an opposing side by a second surface, and having a first region and a second region surrounded by the first region. The first surface may be interposed between the first side and the second surface and the second surface may be interposed between the first surface and the second side. The pedestal base may also include a coolant inlet fluidically connected with the first internal plenum volume and a plurality of first vanes distributed throughout the first region of the first internal plenum volume, each first vane defining a corresponding first reference plane that is tangent to a corresponding spiral reference path that spirals outward from a center of the pedestal base.

In some implementations, at least some of the first vanes may be flat. In some additional or alternative implementations, at least some of the first vanes may be curved.

In some implementations, the spiral reference paths may all have the same chirality.

In some implementations, the spiral reference paths may all have the same spiral shape and at least some of the spiral reference paths may be at different azimuthal positions.

In some implementations, the first vanes within a first sub-region of the first region may have a first density, the first vanes within a second sub-region of the first region may have a second density, the first density may be higher than the second density, and the first sub-region may be the same shape and size as the second sub-region, may have a center that is spaced the same distance from the center axis as a center of the second sub-region, and may not overlap with the second sub-region.

In some implementations, the second surface may include one or more sub-portions that are sloped at one or more oblique angles to a second reference plane that is perpendicular to the center axis.

In some implementations, the one or more sub-portions may include a first sub-portion and a second sub-portion, the first sub-portion may surround the second sub-portion, the first sub-portion and the second sub-portions may both have conical frustum shapes, the conical frustum of the first sub-portion may decrease in distance from the first side with increasing distance from the center axis, and the conical frustum of the second sub-portion may increase in distance from the first side with increasing distance from the center axis.

In some implementations, the pedestal base may further include a second internal plenum volume radiating outward from the center axis and interposed between the first internal plenum volume and the second side, and the pedestal base may further include a plurality of inter-plenum ports fluidically connecting the first internal plenum volume with the second internal plenum volume.

In some implementations, the inter-plenum ports may be distributed along an outer edge of the first internal plenum volume.

In some implementations, the second internal plenum volume may be at least partially bounded on one side by a third surface and at least partially bounded on an opposing side by a fourth surface, and the pedestal base may further include a plurality of support columns distributed within the second plenum volume and spanning between the third surface and the fourth surface.

In some implementations, the pedestal base may further include one or more purge gas plenums located in between the first side and the second side. The pedestal base may further include a plurality of purge gas riser passages, each purge gas riser passage fluidically connecting a corresponding port on the first side with one of the one or more purge gas plenums.

In some implementations, the purge gas riser passages may extend through the first internal plenum volume and the second internal plenum volume, and the purge gas riser passages may be fluidically isolated from the first internal plenum volume and the second internal plenum volume.

In some implementations, at least some of the purge gas riser passages may each be located within a corresponding column structure spanning between first surface and the second surface.

In some implementations, the one or more purge gas plenums may be a single, annular purge gas plenum.

In some implementations, the pedestal base may further include a deflector feature that protrudes from the first surface towards the second surface.

In some implementations, the deflector feature may be axially symmetric. In some implementations, the deflector feature may be axially symmetric about the center axis. In some implementations, the deflector feature may be a conical frustum.

In some implementations, the pedestal base may further include a plurality of second vanes located within the second region, and the second vanes may extend along curved paths that spiral outward from the center axis.

In some implementations, the pedestal base may further include an inner wall that partitions the first interior plenum volume into the first region and the second region, the coolant inlet may fluidically connect with the first internal plenum volume within the second region and at a location that is radially offset from the center axis, and the inner wall may have a plurality of apertures that fluidically connect the first region with the second region within the first internal plenum volume.

In some implementations, the coolant inlet may fluidically connect with the first internal plenum volume within the second region and at a location that is centered on the center axis, and the deflector surface may be centered on the center axis.

In some implementations, the pedestal base may be made of metal.

In some implementations, the pedestal base may be additively manufactured.

In some implementations, the apparatus may further include a semiconductor processing chamber having an interior volume. The pedestal base may be positioned within the interior volume.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts a cross-sectional view of an example pedestal base 104.

FIG. 2 shows representational grain boundaries taken in a vertical plane (left side) and horizontal plane (right side) in an example component made using an example DMLM process.

FIG. 3 depicts a section view of the pedestal base of FIG. 1 along a plane that intersects with a first internal plenum volume of the pedestal base.

FIG. 4 depicts a section view of the pedestal base of FIG. 1 along the same plane as FIG. 3, but in the opposite direction.

FIG. 5 depicts a section view of the pedestal base of FIG. 1 along a plane that intersects with a second internal plenum volume of the pedestal base.

FIG. 6 depicts a section view of the pedestal base of FIG. 1 along the same plane as FIG. 5, but in the opposite direction.

FIG. 7 depicts a further sectional perspective view of the pedestal base of FIG. 1 that passes through a purge gas plenum.

FIG. 8 depicts a top sectional view of the first internal plenum volume of the pedestal base of FIG. 1.

FIG. 9 depicts a cross-sectional top view of a first internal plenum volume of a pedestal base having first vanes that are evenly distributed throughout a first region of the first internal plenum volume.

FIG. 10 depicts a top section view of an example implementation in which a coolant inlet is centered on the center axis of a pedestal base.

FIG. 11 depicts a top sectional view of an example pedestal base having a first internal plenum volume that includes curved first vanes within it.

FIG. 12 depicts an example semiconductor processing chamber that includes a pedestal base that may be implemented as discussed herein.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

As noted previously, semiconductor processing tools or chambers typically use a pedestal to support a wafer during processing operations. Such pedestals may incorporate a variety of subsystems to facilitate processing operations, including, for example, electrodes that may be used to generate RF energy to spark plasmas within the chamber, heaters and cooling systems for thermal management of the wafer, lift pin mechanisms for raising and lowering the wafer from and onto the pedestal, and/or chucking systems for clamping the wafer in place during processing operations.

In particular, cooling and temperature control systems of pedestals may be particularly important. Semiconductor wafers supported by the pedestal may be in close contact with the pedestal and have a much lower thermal mass than the pedestal, thereby making them very responsive to changes in temperature across the pedestal. In other words, any temperature non-uniformities in the pedestal will tend to be immediately mirrored in the wafers supported thereby. Such temperature variations may result in processing non-uniformities in the wafer that are undesirable.

Typical cooling systems in pedestals feature one or more channels that are typically machined into a solid block of material used to provide part of a pedestal base, e.g., following a serpentine or other meandering path that causes the channel(s) to traverse across most of the pedestal base. This component is then mated with a capping plate that is bonded or otherwise attached to the component in order to cap the channel(s) and turn the channel(s) into enclosed passage(s). Coolant is then circulated through the channel(s) in order to remove heat from the pedestal base during operation.

The present inventors conceived of a new type of pedestal base in which the coolant is not circulated within discrete channels within the pedestal base but is instead flowed through a relatively open plenum volume that has distributed within it a plurality of vanes that are arranged in a spiral-like pattern, e.g., similar to the flow field in a vortex. In such a pedestal base, the coolant may be flowed into the pedestal base via a coolant inlet that is located near or at the center of the plenum volume and is then caused to flow radially outward. During such outward radial flow, the coolant may be redirected by the vanes, inducing the coolant to flow along spiral flow paths, similar to the flow field within a vortex. Such vortex flow patterns may help evenly distribute the coolant throughout the plenum volume, thereby providing a more uniform temperature across the pedestal base (or, more technically, the exterior surface of the pedestal closest to the plenum volume). At the same time, the relatively open internal plenum volume or volumes that may be used in such pedestal bases (as compared with pedestal bases using serpentine or meandering cooling channels that constrain fluid flow to specific paths) result in much lower pressure drops as the coolant flows through the internal plenum volume(s) of the pedestal base, thereby increasing the overall thermal efficiency of the cooling system. This, in turn, may act to reduce the response time for such pedestal bases, i.e., the increasing thermal efficiency of such pedestal bases may allow such pedestal bases to be more quickly heated or cooled to a given target temperature, thereby reducing the amount of time that may be needed in order to bring a semiconductor wafer supported thereby to a target temperature. As a result, faster wafer processing and increased throughput may be achieved using pedestal bases as disclosed herein.

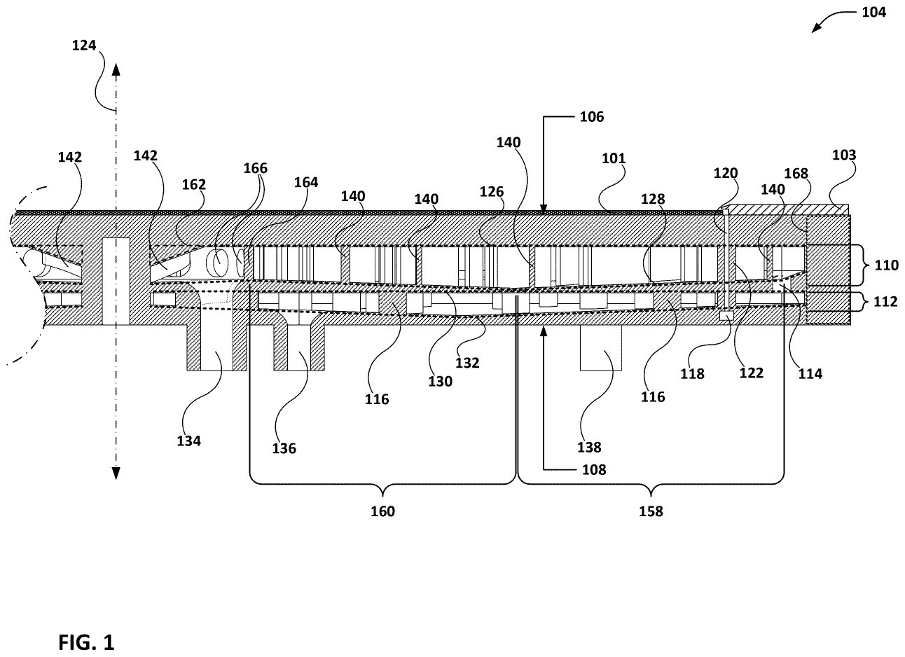

FIG. 1 depicts a cross-sectional view of an example pedestal base 104. The pedestal base 104 may be generally circular in shape, taking the form of a thick plate-like structure having a center axis 124. In FIG. 1, only about half of the pedestal base is shown; the undepicted half may be generally similar in structure.

The pedestal base 104 may be manufactured as a single component or as multiple components, e.g., layers, that may be bonded or otherwise connected together. The pedestal base 104, in this example, may include a first internal plenum volume 110 and a second internal plenum volume 112 that are both located in between a first side 106 and a second side 108 of the pedestal base 104 and radiate outward from the center axis 124 and are encircled by an outer wall 168. The first side 106 of the pedestal base 104 may be designed to contact and thereby support a semiconductor wafer 101, or another structure, like a thin top-plate containing an electrostatic clamping electrode, that supports the wafer 101 during wafer processing operations and may generally be oriented upwards when installed in a semiconductor processing chamber. The second side 108, in turn, would generally be oriented downward when the pedestal base 104 is in an in-use configuration in the semiconductor processing chamber.

The first internal plenum volume 110 may be bounded at least partially on one side by a first surface 126 and at least partially, on an opposing side, by a second surface 128. Similarly, the second internal plenum volume 112 may be bounded at least partially on one side by a third surface 130 and at least partially, on an opposing side, by a fourth surface 132. The first internal plenum volume 110 and the second internal plenum volume 112 are, in this example, both generally cylindrical in overall shape, of a similar size, and generally coextensive with one another when viewed along the center axis 124. The first internal plenum volume 110 is also, in this example, fluidically connected with the second internal plenum volume 112 via a plurality of inter-plenum ports 114 that are distributed about the peripheries or outer edges of the first internal plenum volume 110 and/or the second internal plenum volume 112. It will be understood that the first surface 126 may be interposed between the first side 106 and the second surface 128 and that the second surface 128 may be interposed between the first surface 126 and the second side 108. Similarly, it will be understood that the third surface 130 may be interposed between the second surface 128 and the fourth surface 132 while the fourth surface 132 is interposed between the second side 108 and the third surface 130.

Coolant that is introduced from one or more coolant inlets 134 into the first internal plenum volume 110 may flow from a center region of the first internal plenum volume 110 radially outward to the inter-plenum ports 114, through the inter-plenum ports 114 into the second internal plenum volume 112, and then radially inward to one or more coolant outlets 136. In other implementations, however, the second internal plenum volume 112 may be omitted entirely or may extend towards the center axis to a lesser degree than depicted, e.g., only to about half of the radius of the pedestal base 104. If the second internal plenum volume 112 is omitted entirely, the inter-plenum ports 114 may be replaced with a plurality of coolant outlets 136.

In the implementation of FIG. 1, the coolant inlet is fluidically connected with the first internal plenum volume 110 at a location that is off-center from the center axis 124. Such an implementation may be used when other components or features may be located in the center of the pedestal base, making it impractical or impossible to locate the coolant inlet 134 on the center axis 124. For example, the pedestal base 104 may include one or more radio-frequency or electrostatic clamping electrodes within it or in a component in contact with the first side 106, and electrical connectors or cables that may provide power to such electrodes may be located along the center axis 124. In FIG. 1, it can be seen that there is a blind hole in the pedestal base 104 along the center axis 124 that may, for example, be provided to allow an electrical cable or connector for such an electrode (not shown).

In some implementations of pedestal bases 104 in which the coolant inlet 134 is positioned off-center from the center axis, the first internal plenum volume 110 may optionally be equipped with an inner wall 164. The inner wall 164 may define a boundary between a first region and a second region of the first internal plenum volume 110. The first region may include first vanes 140 and may encircle the second region, which may include the coolant inlet 134. The inner wall 164 may have a plurality of apertures 166 through it, e.g., a circular array of apertures 166, that may serve as flow restrictions that may help more evenly distribute the coolant that is flowed into the second region via the coolant inlet 134 into the first region, where it may encounter the first vanes 140. In some implementations, the second region may also include a deflector feature 162 and/or second vanes 142, which may also help more evenly distribute the coolant across the inner wall 164.

In some implementations, the pedestal base 104 may also include one or more purge gas plenums 118 that may provide purge gas provided from a purge gas inlet 138 to a plurality of purge gas riser passages 120 that may fluidically connect with a circumferentially distributed set of purge gas ports on the first side 106. The purge gas riser passages 120 may, in some instances, pass through the first internal plenum volume 110 and/or the second internal plenum volume 112, e.g., via column structures 122 that may fluidically isolate the purge gas riser passages 120 from the first internal plenum volume 110 and the second internal plenum volume 112. In some instances, an edge ring 103 may be placed on top of the pedestal base 104 and include features along its interior diameter that guide and focus purge gas from the purge gas riser passages 120 to flow radially inward across the top outer edge of the wafer 101 in order to prevent processing gases delivered to the wafer 101 from migrating to the underside of the wafer 101 and potentially causing damage thereto.

If the second internal plenum volume 112 is used in an implementation, some such instances thereof may include a plurality of support columns 116 or other support features spanning between the third surface 130 and the fourth surface 132. Such support features may provide rigidity to the overall pedestal base 104 structure.

The pedestal base 104 may, as noted earlier, be a single-piece structure or multiple layers that are bonded together. Regardless of how the pedestal base 104 is ultimately assembled, it will be understood that the pedestal base 104, or sub-portions thereof, may in some instances be manufactured using additive manufacturing techniques, such as selective laser melting (SLM) (which may be used to produce ceramic or silicon versions of such pedestal bases) or direct metal laser melting (DMLM) (which may be used to produce metal versions thereof). In particular, the pedestal base designs discussed herein may be particularly suitable for being manufactured using laser powder-bed fusion (LPBF) additive manufacturing techniques, which may include manufacturing processes such as SLM, DMLM, SLS (selective laser sintering), and DMLS (direct metal laser sintering), all of which may be used to create metal-based components (and some of which, like SLS and SLM, may be used to create ceramic-based components). However, this disclosure is not limited to such techniques, and any suitable additive manufacturing process that is able to make components having geometries such as those discussed herein may be used.

In most additive manufacturing processes, a part is manufactured by adding material to the part one horizontal layer at a time; such layers may be extremely thin, e.g., 0.02 mm at a time is possible for DMLM parts. In DMLM, for example, a platen supporting a part is gradually lowered relative to a reference plane. The platen forms the “floor” of a cavity that is used to contain the part being manufactured. Each time the platen is lowered, powdered material is added to the cavity and then leveled so as to be level with the reference plane. A laser then scans across the reference plane and applies heat to the uppermost layer of powdered material in the regions where structure is desired, melting the powder granules to each other and to any underlying, previously fused structure. Once a particular layer is done, the platen may be lowered slightly, a new layer of powdered material may be applied, and the laser melting process repeated. This process is repeated until the part is complete, at which point the cavity of the DMLM device will be filled with unmelted powdered material having buried within it the additively manufactured component.

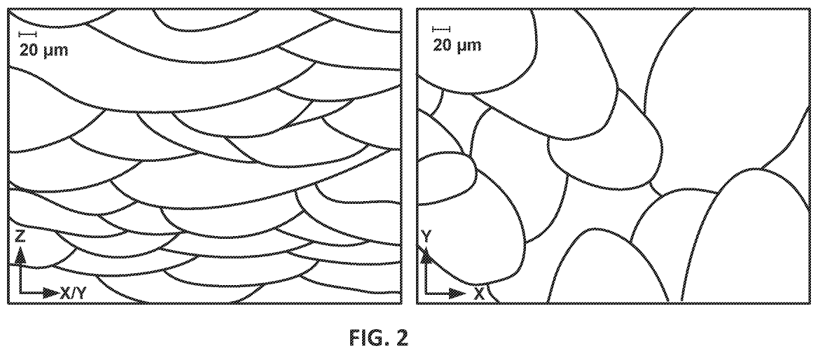

Such additively manufactured components typically have a very fine grain microstructure as compared with bulk-manufactured components (e.g., such as components made by casting in which molten material is formed into the desired component in generally a single operation as opposed to a small number of grains being fused together at a time over the course of many sequential operations as is done in SLM or DMLM), i.e., a structure that is formed through the fusion of small grains of solid material through the selective application of heat provided by a laser. Such additively manufactured components also, in many cases, tend to have a microstructure that is noticeably directional, with micrograins having profiles in the XY plane that are more rounded and larger than the profiles of such micrograins in a plane parallel to the Z direction (with the XY plane corresponding to the horizontal plane, and the Z direction corresponding to the vertical direction, relative to the component as positioned during the additive manufacturing process). FIG. 2, for example, shows representational grain boundaries taken in a vertical plane (left side) and horizontal plane (right side) in an example component made using one example DMLM process; as can be seen, the size of the grains in the vertical plane exhibit a high degree of asymmetry with respect to their size in the Z-direction compared to their size in either the X or Y directions. The micrograins tend to be much longer in the X and/or Y directions than they are thick in the Z direction. This micrograin structure may be referred to herein as being an anisotropic micrograin structure, which should be understood to differentiate it from micrograin structures in which the micrograins, while exhibiting variation in size and shape, do not generally exhibit dimensional variance that is tied to a particular axis. It will be understood that at least some of the additively manufactured pedestal bases discussed herein may exhibit such anisotropic micrograin structure.

The use of such additive manufacturing techniques permits the adoption of pedestal base geometries that would be difficult and costly to achieve using only conventional machining (subtractive machining) techniques such as milling, drilling, and/or turning.

In additively manufactured components featuring large, internal cavities (such as the first internal plenum volume 110 and/or the second internal plenum volume 112), LPBF techniques may encounter difficulty with accurately creating “overhanging” surfaces, e.g., the “ceiling” of a large internal cavity in a part. For example, when manufacturing such surfaces, the internal volume of the cavities being capped may be filled with, for example, metal powder. When the top layer of such metal powder is then melted to form the ceiling, this may result in a large, thin sheet of otherwise unsupported metal material that may, due to the heat loads involved, warp or otherwise experience degradation that makes such parts unusable. In order to avoid such issues, one or more of the first surface 126 through the fourth surface 132 may be manufactured with a slight slope, e.g., such that such surfaces are at an oblique angle, and more specifically a shallow oblique angle, with respect to a second reference plane that is perpendicular to the center axis 124. By sloping such overhanging surfaces slightly, the amount of overhanging surface that is created during any single pass of the additive manufacturing printer head and not supported by a previously deposited layer of fused material may be limited to a relatively small region, thereby mitigating or eliminating the warpage and other issues that may result from additively manufacturing a large, overhanging surface capping a large internal cavity such as the first internal plenum volume 110 and/or the second internal plenum volume 112. In the depicted pedestal base 104 of FIG. 1, for example, the pedestal base 104 is additively manufactured in an “upside down” configuration (relative to how it is oriented in FIG. 1), and the second surface 128 and the fourth surface 132 are both sloped at a slight, e.g., ~2°, from horizontal, oblique angle. In some instances, such obliquely sloped surfaces may be subdivided into different sub-portions that may be sloped in different directions. For example, in FIG. 1, the second surface 128 is divided into a first sub-portion 158 that encircles as second sub-portion 160. Both the first sub-portion 158 and the second sub-portion 160 may be sloped at a shallow oblique angle relative to a reference plane that is perpendicular to the center axis 124, but the directions of such slopes may be reversed between the two sub-portions. For example, the first sub-portion 158 may have a conical frustum shape in which the distance between the conical frustum and the first side 106 decreases or increases with increasing distance from the center axis 124 while the second sub-portion 160 may have a conical frustum shape in which the distance between the conical frustum and the first side 106 increases or decreases, respectively, with increasing distance from the center axis 124. It will be understood that other implementations may be manufactured in the opposite orientation, e.g., “right-side up” or in a mix of orientations, e.g., a two-part design in which one half is manufactured in a “right-side up” orientation and the other half is manufactured in an “upside down” configuration and the two halves then joined, e.g., using brazing, diffusion bonding, etc.

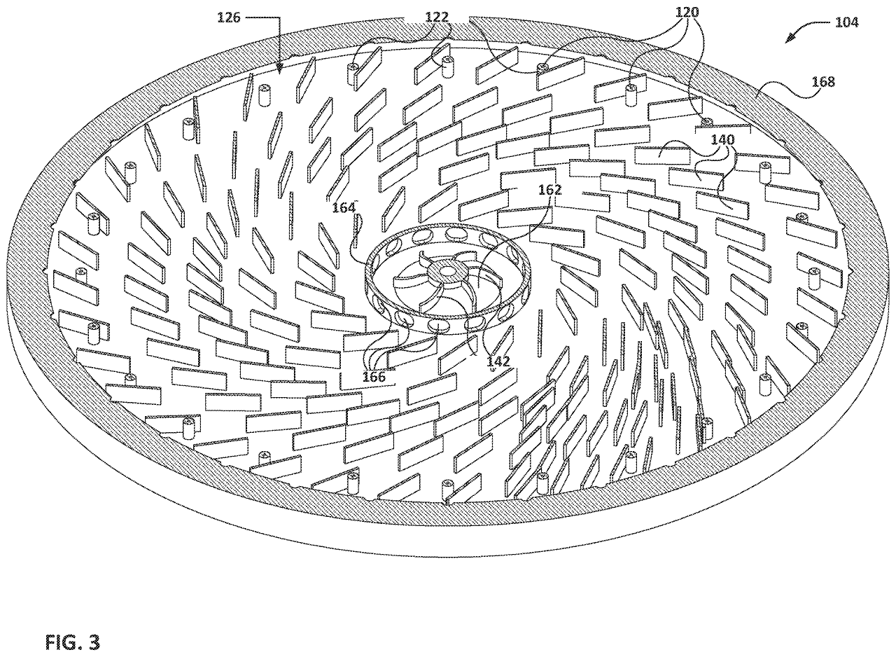

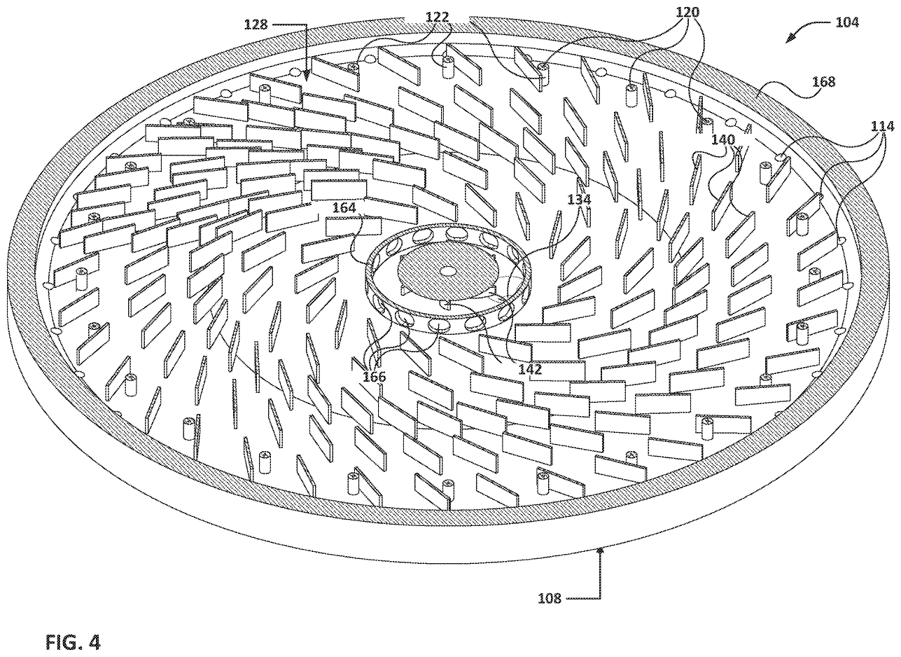

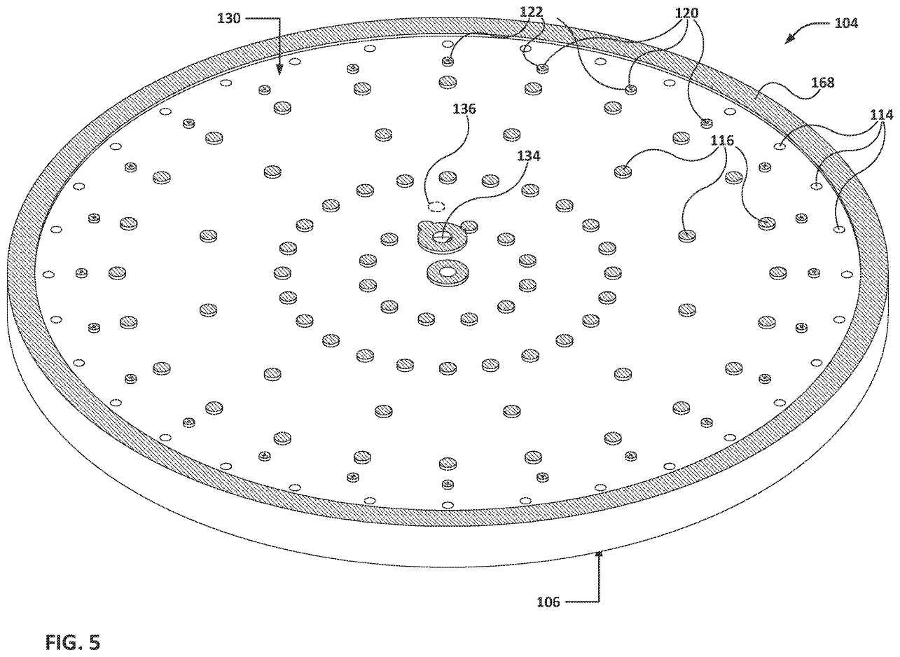

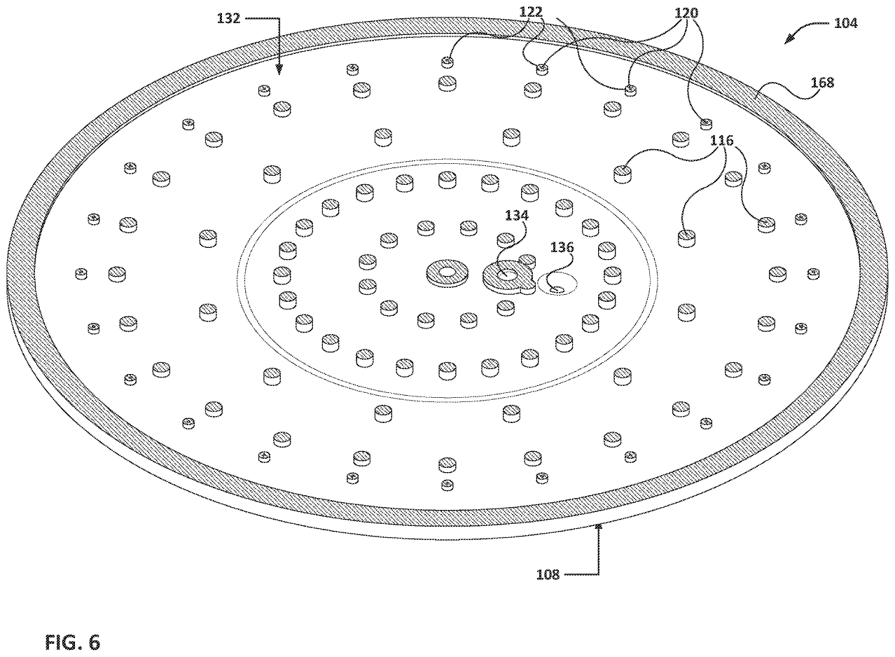

FIGS. 3 through 7 depict various perspective section views of the example pedestal base 104 of FIG. 1. FIG. 3 depicts a section view of the pedestal base 104 along a plane that intersects with the first internal plenum volume 110 and is oriented towards the first surface 126. FIG. 4 depicts a section view of the pedestal base 104 along the same plane as FIG. 3, but in the opposite direction, towards the second surface 128. FIG. 5 depicts a section view of the pedestal base 104 along a plane that intersects with the second internal plenum volume 112 and is oriented towards the third surface 130. FIG. 6 depicts a section view of the pedestal base 104 along the same plane as FIG. 5, but in the opposite direction, towards the fourth surface 132.

In FIG. 3, the first internal plenum volume 110 is visible in the sectioned area of the pedestal base 104. As can be seen, a plurality of column structures 122 extend upward from the first surface 126 and towards the second surface 128 (not visible here, but see FIG. 4). To be clear, the view of FIG. 3 is from the bottom looking up—the first side 106 of the pedestal base 104 is thus on the underside of the depicted structure. The column structures 122 allow the purge gas riser passages 120 that are located within each column structure 122 to be fluidically isolated from the first internal plenum volume 110, thereby allowing purge gas to be distributed therethrough without the possibility of coolant leaking into the purge gas flow path.

Perhaps most prominently visible in FIG. 3 are the first vanes 140, which may be distributed throughout the first internal plenum volume 110. The first vanes 140 may, for example, be distributed along a plurality of spiral reference paths that spiral outwards from the center axis 124 of the pedestal base 104. As can be seen, in most cases, the first vanes 140 are separate, discrete structures that are all the same size and shape. However, as can be seen in some instances at lower right, there may be some instances in which the first vanes 140 may have different lengths or shapes.

Also visible in more clarity in FIG. 3 is the inner wall 164 and the radial apertures 166 that pass through the inner wall 164, as well as the deflector feature 162 and the second vanes 142. The deflector feature 162 is, in this example, a conical frustum surface. However, in other implementations, the deflector feature 162 may have other shapes, e.g., a curved cross-sectional profile, instead. The deflector feature 162 may protrude from the first surface 126 towards the second surface 128 and may have a generally axially or radially symmetric shape, e.g., about the center axis 124. The second vanes, as shown in FIG. 3, may be spiral-shaped and radiate outward from the center axis 124. However, it will be understood that other implementations may omit the second vanes 142 and/or the deflector feature 162 entirely, or use other geometries of second vanes 142, e.g., straight second vanes 142.

FIG. 4 depicts the first internal plenum volume 110 from the opposite perspective as in FIG. 3. Many of the same structures that are visible in FIG. 3 are thus visible in FIG. 4 as well; further discussion of these elements is omitted in the interest brevity. As can be seen in FIG. 4, the coolant inlet 134 is fluidically connected with the first internal plenum volume 110 at a location that is offset from the center axis 124 but located within the perimeter of the inner wall 164. Also visible in FIG. 4 are the inter-plenum ports 114 that are distributed about the outer edge of the first internal plenum volume 110. When coolant is flowed from the coolant inlet 134 into the first internal plenum volume, it first starts to swirl within the inner wall 164 before flowing radially outward through the apertures 166 and into the first region of the first internal plenum volume 110, where it is guided by the first vanes 140 into a vortex-like flow pattern before it reaches the inter-plenum ports 114, through which the coolant exits the first internal plenum volume 110.

FIG. 5 depicts the second internal plenum volume 112 from the same perspective as FIG. 3. As in FIGS. 3 and 4, column structures 122 are visible extending up from the third surface 130. The column structures 122, like those in the first internal plenum volume 110, fluidically isolate the purge gas riser passages 120 from the second internal plenum volume 112.

Also visible in FIG. 5 are the inter-plenum ports 114, which are positioned along the periphery or outer edge of the second internal plenum volume 112. Coolant from the first internal plenum volume 110 may flow through the inter-plenum ports 114, into the second internal plenum volume 112, and towards the center of the second internal plenum volume 112, where it may flow out of the second internal plenum volume 112 via the coolant outlet 136. It will be understood that the coolant outlet is actually located on the fourth surface 132, but its general location is represented in FIG. 5 by a dotted circular outline for reference.

FIG. 5 also illustrates the distribution of the support columns 116. As can be seen, the support columns 116 are generally evenly distributed throughout the second internal plenum volume 112, but are also small enough in size and low enough in density that they do not significantly affect the flow of the coolant towards the coolant outlet 136.

FIG. 6 depicts the second internal plenum volume 112 from the opposite perspective as that of FIG. 5. As can be seen, the coolant outlet 136 is visible in this view.

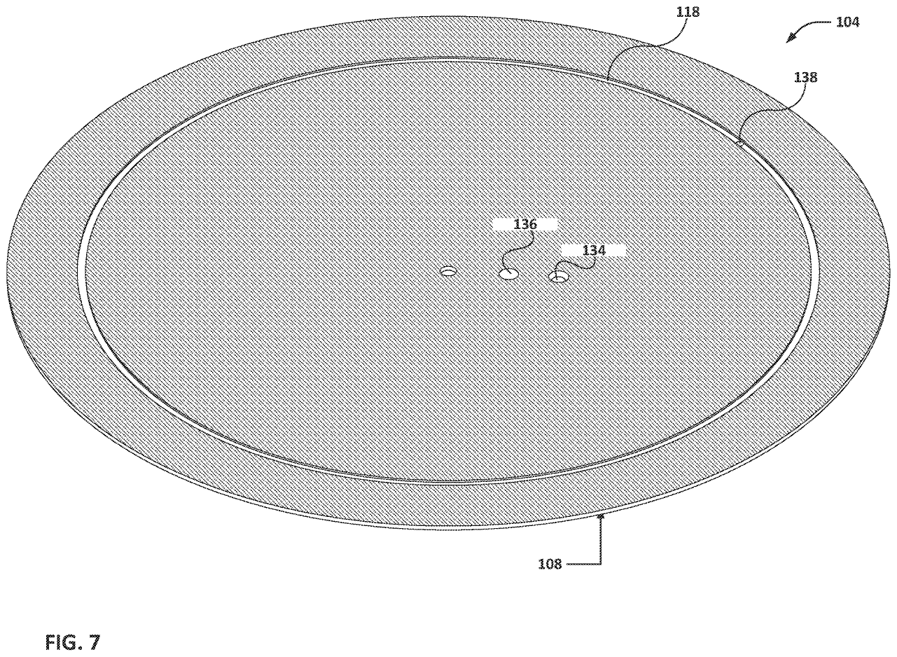

FIG. 7 depicts a further sectional perspective view that passes through the purge gas plenum 118. As can be seen, the purge gas plenum 118 is a single, annular plenum that is supplied purge gas via a single purge gas inlet 138. The purge gas that is introduced into the purge gas plenum 118 may then flow around the purge gas plenum 118 and into the purge gas riser passages 120 before exiting the first side 106 of the pedestal base 104. It will be understood, however, that the purge gas plenum 118 may also be provided as multiple separate plenums, e.g., each a semicircular or quarter arc, that are provided purge gas via corresponding purge gas inlets 138.

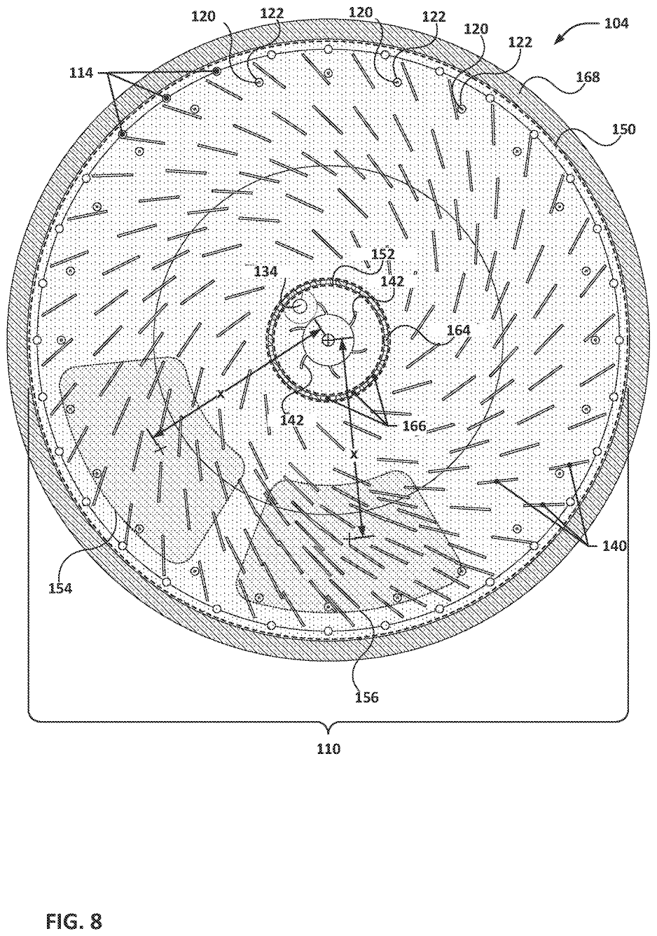

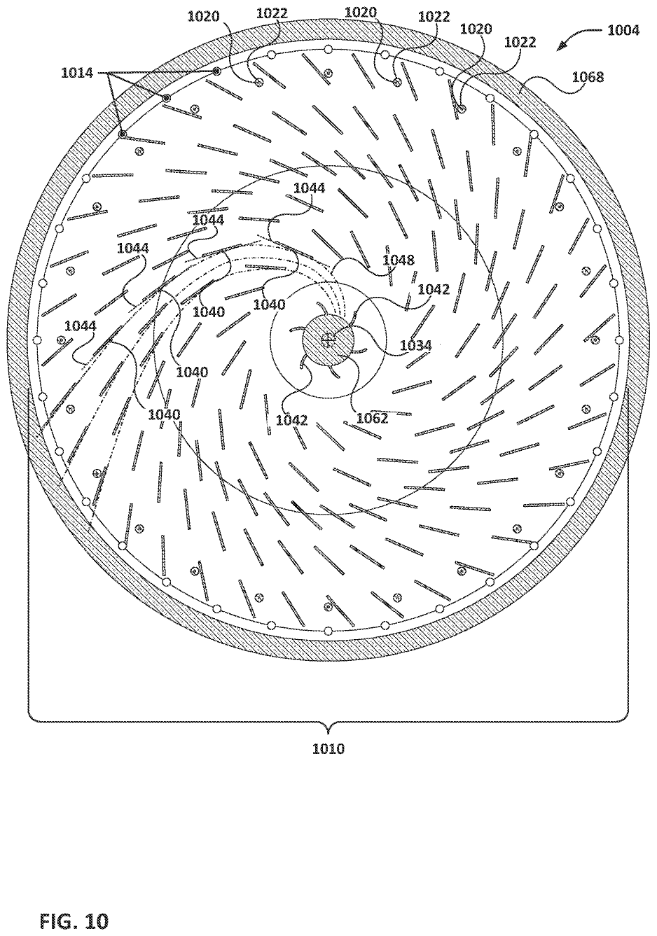

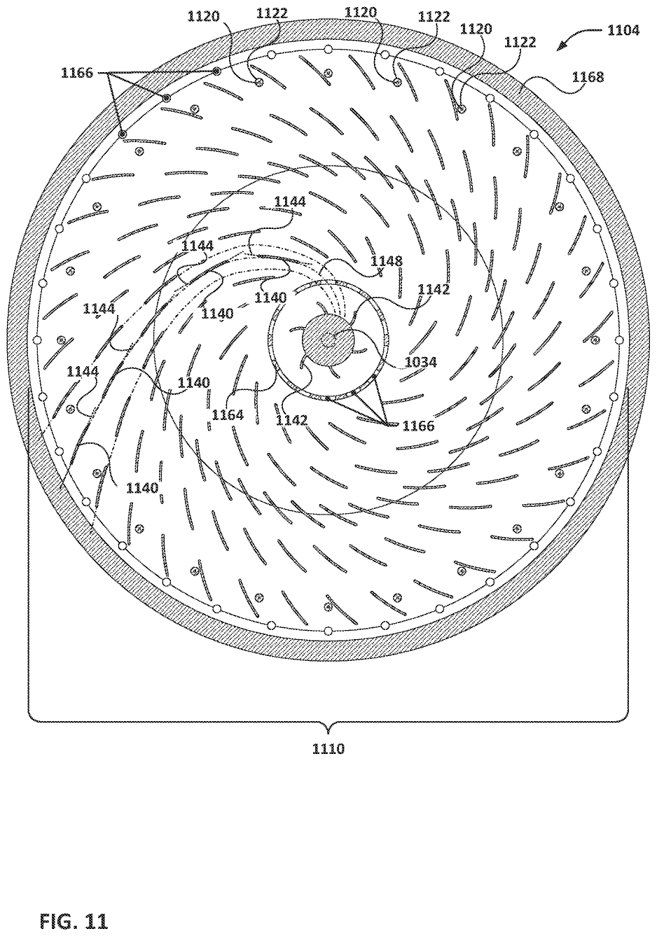

FIG. 8 depicts a top sectional view of the first internal plenum volume 110. As can be seen, the first internal plenum volume 110 may be divided into a first region 150 that encircles a second region 152. The first vanes 140 may be distributed throughout the first region 150, generally along a plurality of spiral reference paths (see later discussion of FIGS. 10 and 11 for further detail on such spiral reference paths). In this example, the inner wall 164 demarks a boundary between the first region 150 and the second region 152, although the boundary between the first region 150 and the second region 152 is not necessarily tied to the location of the inner wall 164 (and, as discussed earlier, in some cases the inner wall 164 may be omitted entirely and thus cannot serve as a boundary between the first region 150 and the second region 152).

Also shown in FIG. 8 are a first sub-region 154 and a second sub-region 156. The first sub-region 154 and the second sub-region 156 are non-overlapping but have the same size, the same shape, the same orientation relative to a corresponding reference axis extending radially outward from the center axis 124, and center locations that are offset the same distance “X” outward from the center axis 124. However, a first density of the first vanes 140 in the first sub-region 154 is different from a second density of the first vanes 140 in the second sub-region 156. In this example, the second density of the first vanes 140 in the second sub-region 156 is higher than the first density of the first vanes 140 in the first sub-region 154. For clarity, the “density” of the first vanes 140 within a given sub-region 154 or 156 is to be understood to be the ratio of the total cross-sectional area (in a plane that is perpendicular to the center axis 124) of the first vanes 140 or portions of the first vanes 140 that lie within that sub-region 154 or 156 to the total cross-sectional area of that sub-region 154 or 156 in that same sectioning plane. This reflects the fact that pedestal bases 104 disclosed herein may have asymmetric distributions of first vanes 140 within the first region 150 that may be used to increase or decrease coolant flow to certain zones of the pedestal base 104, thereby allowing for temperature non-uniformities in the pedestal base 104 to be compensated for and reduced. For example, increasing the density of the first vanes 140 within a particular area will tend to constrict the flow paths between such vanes, thereby increasing the flow resistance that fluid flowing through that area will experience. As a result, such fluid will tend to flow towards, and through, areas of the first region 150 that have fewer first vanes 140. This allows the coolant flow rate at various locations across the first region 150 to be modified to either have increased fluid flow or decreased fluid flow at various locations. Since the rate of heat transfer from the pedestal base 104 to the coolant within the first internal plenum volume 110 varies with localized flow rate of the coolant within the first internal plenum volume, the heat transfer performance of the pedestal base 110 at any given location within the first region 150 may be increased by using a lower density of first vanes 140 in that location and decreased by using a higher density of first vanes 140 in that location.

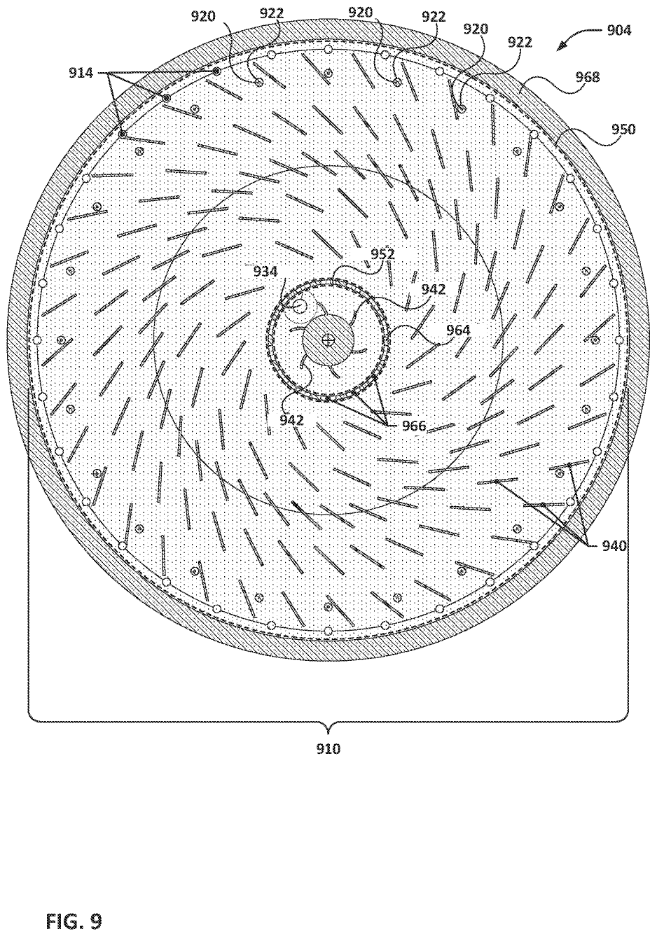

While the example pedestal base 104 in the discussion above has focused on an implementation in which there is an uneven distribution of the first vanes 140 within the first region 150, other implementations may feature a symmetric distribution of the first vanes 140 within the first region 150. FIG. 9 depicts a cross-sectional top view of a first internal plenum volume 910 of a pedestal base 904 having first vanes 940 that are evenly distributed throughout a first region 950 of the first internal plenum volume 710. An outer wall 968 encircles the first internal plenum volume 910. As can be further seen, the first vanes 940 in the example pedestal base 904 of FIG. 9 are arranged in several circular patterns about the center axis of the pedestal base, and exhibit radial symmetry about the center axis. Such an implementation may be used when the pedestal base 904 does not exhibit any (or exhibits very little) circumferential non-uniformity in temperature.

The pedestal base 104 may otherwise be similar to the pedestal base 104 in construction, e.g., having an inner wall 964 with apertures 966 encircling a second region 952 of the first internal plenum volume 910 and a coolant inlet 934 located within the second region 952, a deflector feature and a plurality of second vanes 942 located within the inner wall 964, a plurality of column structures 922 with purge gas riser passages 920 extending upwards therethrough, and a plurality of inter-plenum ports 914 distributed about the outer perimeter of the first internal plenum volume 910 to fluidically connect the first internal plenum volume 910 with a second internal plenum volume (not shown) that may, for example, be similar to the second internal plenum volume 112.

In the previously discussed examples, the coolant inlet has been positioned so as to be off-center from the center axis of the pedestal base. However, as discussed earlier, the coolant inlet may optionally be centered on the center axis. FIG. 10 depicts a top section view of an example implementation in which a coolant inlet 1034 is centered on the center axis of a pedestal base 1004. In FIG. 10, the view is a top section view that looks down onto a first internal plenum volume 1010 of the pedestal base 1004. As a result, the coolant inlet 1034 would actually be obscured by a deflector feature 1062 that may protrude from a first surface of the pedestal base 1004 and towards a second surface 1028 of the pedestal base 1004. For clarity, however, a dotted outline of the coolant inlet 1034 is provided to show its location relative to the deflector feature 1062, second vanes 1042, and first vanes 1040. Also visible in FIG. 10 are inter-plenum ports 1014, column structures 1022 with purge gas riser passages 1020 extending therethrough, and an outer wall 1068 (although this implementation has no inner wall, in contrast the earlier-discussed pedestal bases 104 and 904).

Also visible in FIG. 10 are some spiral reference paths 1048 (one is labeled and three are shown), which spiral outward from the center axis or region of the pedestal base 1004. It will be understood that only some of the spiral reference paths 1048 of the pedestal base 1004 are shown, and that additional spiral reference paths 1048 may be provided for a given pedestal base. It will also be understood, of course, that the spiral reference paths 1048 may not necessarily be visible paths-they are merely paths that may define the locations and orientations of the first vanes 1040.

For example, each first vane 1040 may define a corresponding first reference plane 1044 that is tangent to one of the spiral reference paths 1048. The corresponding first reference plane 1044 for each first vane 1040 may, for example, simply be provided by one of the two major surfaces of that first vane 1040 if the first vane 1040 in question is flat.

As mentioned above, the first vanes in pedestal bases according to the present disclosure may also have cross-sections that are non-planar, e.g., the first vanes may be curved instead of flat. FIG. 11 depicts a top sectional view of an example pedestal base 1104 having a first internal plenum volume 1110 that includes curved first vanes 1140 within it.

In FIG. 11, the view is a top section view, as with FIG. 10, that looks down onto the first internal plenum volume 1110 of the pedestal base 1104. In this example, the pedestal base 1104 includes inter-plenum ports 1114, column structures 1122 with purge gas riser passages 1120 extending therethrough, an inner wall 1164 with apertures 1166 extending therethrough, and an outer wall 1168. A deflector feature and second vanes 1142 are also shown within the inner wall 1164.

Also visible in FIG. 11 are spiral reference paths 1148 (one is labeled and three are shown), which spiral outward from the center axis or region of the pedestal base 1104. As with the spiral reference paths 1048, only some of the spiral reference paths 1148 of the pedestal base 1104 are shown, and it will be understood that additional spiral reference paths 1148 may be provided for a given pedestal base 1004.

As can be seen in FIG. 11, the first vanes 1140 are slightly curved in profile, conforming more to the spiral reference paths 1148 along which each first vane 1140 lies. As with the example from FIG. 10, the first vanes 1140 may each define a corresponding first reference plane 1144 that is tangent to one of the spiral reference paths 1148. Each first reference plane 1144 may, for example, be a plane that passes through opposing ends of the corresponding first vane 1140 along the long axis of the first vane 1140.

It can be seen in FIGS. 10 and 11 that the spiral reference paths may generally all have the same chirality, i.e., they all spiral outward with the same handedness (clockwise or counterclockwise). In some implementations, the spiral reference paths may also all have the same spiral shape (although they may be at different azimuthal positions). For example, the three spiral reference paths shown in FIGS. 10 and 11 are all identical spiral shapes but are positioned at three different azimuthal positions.

As alluded to earlier, the pedestal bases discussed herein may be made from any of a variety of materials, including, for example, metals or ceramics, and may be manufactured, at least in part, using additive manufacturing techniques. In implementations in which metal-based additive manufacturing, e.g., direct metal laser melting, direct metal laser sintering, or selective laser melting, is used, the resulting pedestal bases may, for example, exhibit an anisotropic micrograin structure. Various example materials that may be used to manufacture pedestal bases according to the disclosure herein may include aluminum alloys that are then coated with an aluminum oxide coating, high-nickel alloys such as Hastelloy C22 (a nickel-chromium-molybdenum superalloy having, by percentage mass, <% 0.015 C, 20%-22.5% Cr, 2%-6% Fe, ≤0.5% Mn, ≤0.08% Si, 12.5%-14.5% Mo, ≤2.5% Co, ≤0.02% P, ≤0.02% S, ≤0.35% V, 2.5%-3.5% W, and the balance Ni), or other suitable material. Other potentially suitable materials may include alloys such as Inconel 625 (a nickel-chromium alloy having, by percentage mass, <% 0.1 C, 20%-30% Cr, ≤5% Fe, ≤0.5% Mn, ≤0.5% Si, 8%-10% Mo, ≤1% Co, ≤0.015% P, ≤0.015% S, ≤0.4% Al, ≤0.4% Ti, 3.15%-4.15% Nb (+Ta), and the balance Ni) or Inconel 718 (a nickel-chromium alloy having, by percentage mass, <% 0.08 C, 17%-21% Cr, 17% Fe, ≤0.35% Mn, ≤0.35% Si, 2.8%-3.3% Mo, ≤1% Co, ≤0.015% P, ≤0.015% S, 0.2%-0.8% Al, 0.65%-1/15% Ti, 4.75%-5.5% Nb (+Cb), ≤0.006% B, ≤0.3% Cu, and the balance Ni). In some instances, pedestal bases such as those disclosed herein may be made of non-metallic materials, e.g., ceramics such as alumina (Al₂O₃) or aluminum nitride (AlN).

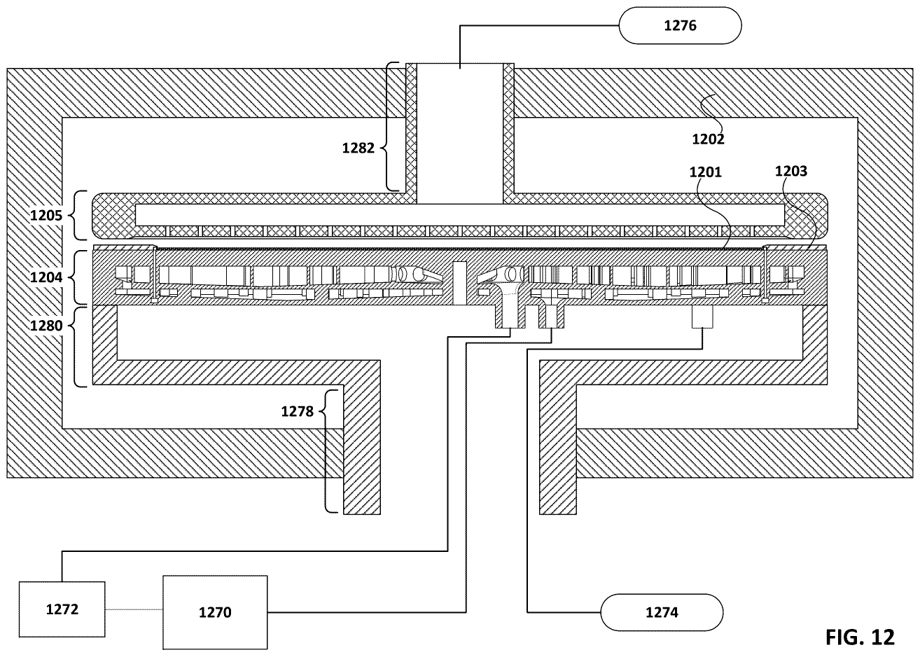

The pedestal bases discussed herein may be used, as indicated earlier, to support wafers during semiconductor processing operations. FIG. 12 depicts an example semiconductor processing chamber 1202 that includes a pedestal base 1204 that may be implemented as discussed herein. The semiconductor processing chamber 1202 may provide a sealable volume that may be sized to provide sufficient space to house the pedestal base 1204 and, for example, a pedestal housing 1280 that is capped by the pedestal base 1204. The pedestal housing 1280 may be supported within the interior space of the semiconductor processing chamber 1202 by a pedestal stem 1278, which may, in some instances, be connected with a vertical lift mechanism that allows the pedestal stem 1278, the pedestal housing 1280, and the pedestal base 1204 to be translated vertically up and down relative to the semiconductor processing chamber 1202 in order to facilitate wafer loading and/or processing operations. The semiconductor processing chamber 1202 may also include a showerhead 1205 that is supported within the semiconductor processing chamber 1202 by a showerhead stem 1282. Processing gas or gases from one or more process gas sources 1276 may be provided to the showerhead 1205 and then flowed across a wafer 1201 supported by the pedestal base 1204 via a plurality of gas distribution ports (not labeled, but visible in FIG. 12) distributed across the underside of the showerhead 1205.

During cooling of the pedestal base 1204, coolant may be pumped by a pump 1272 into the pedestal base via a coolant inlet and then flowed back out of the pedestal base 1204 via a coolant outlet 1236, at which point the coolant may be flowed through a heat exchanger 1270, where it is cooled prior before returning to the pump 1272 and being pumped back into the pedestal base 1204. Purge gas may optionally be provided from purge gas source(s) 1274 and flowed into purge gas inlet 1238, at which point it may be distributed about the periphery of the semiconductor wafer 1201 supported by the pedestal base 1204. An edge ring 1203 may be placed on the pedestal base 1204 such that the purge gas delivered via the purge gas inlet 1238 is directed radially inward or at least so as to shield the outer edge of the semiconductor wafer 1201 from the process gases delivered via the showerhead 1205.

While not shown in the present examples, the pedestal bases discussed herein may have additional features, e.g., through-holes that pass through the first internal plenum volume and, in some cases, the second internal plenum volume that may be used to allow lift pins to pass through the pedestal base in order to lift a wafer placed thereupon off of the pedestal base.

The control of pedestal assemblies having pedestal bases such as are described herein may be facilitated through the use of a controller that may be included as part of a semiconductor processing tool having such a pedestal assembly. The systems discussed above may be integrated with electronics for controlling their operation before and after processing of a semiconductor wafer or substrate. The electronics may be referred to as the “controller,” which may control various components or subparts of the system or systems. The controller, depending on the processing requirements and/or the type of system, may be programmed to control any of the systems disclosed herein, including operation of the various valves that may control the flow of purge gas and/or the evacuation of gas so as to draw a vacuum, operation of heater elements within a pedestal assembly, the operation of various valves that may control the flow of process and/or purge gases, the flow of coolant through the pedestal base, the operation of vertical lift mechanisms for moving pedestal assemblies and/or showerheads and/or lift pins up and down, the operation of electrostatic chucks or clamping electrodes, or various other components that may be included in, or provided in association with, pedestal assemblies as described herein.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular operation using a pedestal assembly as described herein.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control coolant flow operations to a pedestal base as described herein.

Without limitation, pedestal assemblies as described herein may be connected with one or more other pieces of equipment, including a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, or any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers, e.g., FOUPs, to and from tool locations and/or load ports in a semiconductor manufacturing factory.

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. An apparatus for use in semiconductor processing operations, the apparatus comprising:
a pedestal base having a first side and a second side, wherein the pedestal base includes:
a first internal plenum volume radiating outward from a center axis, located between the first side and the second side, at least partially bounded on one side by a first surface and at least partially bounded on an opposing side by a second surface, and having a first region and a second region surrounded by the first region, wherein the first surface is interposed between the first side and the second surface and the second surface is interposed between the first surface and the second side; and
a coolant inlet fluidically connected with the first internal plenum volume; and
a plurality of first vanes distributed throughout the first region of the first internal plenum volume, each first vane defining a corresponding first reference plane that is tangent to a corresponding spiral reference path that spirals outward from a center of the pedestal base.

2. The apparatus of claim 1, wherein at least some of the first vanes are flat.

3. The apparatus of claim 1, wherein at least some of the first vanes are curved.

4. The apparatus of claim 1, wherein the spiral reference paths all have the same chirality.

5. The apparatus of claim 1, wherein the spiral reference paths are all the same spiral shape and at least some of the spiral reference paths are at different azimuthal positions.

6. The apparatus of claim 1, wherein:
the first vanes within a first sub-region of the first region have a first density,
the first vanes within a second sub-region of the first region have a second density,
the first sub-region is the same shape and size as the second sub-region, has a center that is spaced the same distance from the center axis as a center of the second sub-region, and does not overlap with the second sub-region, and
the first density is higher than the second density.

7. The apparatus of claim 1, wherein the second surface includes one or more sub-portions that are sloped at one or more oblique angles to a second reference plane that is perpendicular to the center axis.

8. The apparatus of claim 7, wherein:
the one or more sub-portions includes a first sub-portion and a second sub-portion,
the first sub-portion surrounds the second sub-portion,
the first sub-portion and the second sub-portions both have conical frustum shapes,
the conical frustum of the first sub-portion decreases in distance from the first side with increasing distance from the center axis, and
the conical frustum of the second sub-portion increases in distance from the first side with increasing distance from the center axis.

9. The apparatus of claim 1, wherein:
the pedestal base further includes a second internal plenum volume radiating outward from the center axis and interposed between the first internal plenum volume and the second side, and
the pedestal base further includes a plurality of inter-plenum ports fluidically connecting the first internal plenum volume with the second internal plenum volume.

10. The apparatus of claim 9, wherein the inter-plenum ports are distributed along an outer edge of the first internal plenum volume.

11. The apparatus of claim 9, wherein:
the second internal plenum volume is at least partially bounded on one side by a third surface and at least partially bounded on an opposing side by a fourth surface, and
the pedestal base further includes a plurality of support columns distributed within the second plenum volume and spanning between the third surface and the fourth surface.

12. The apparatus of claim 9, wherein the pedestal base further includes:
one or more purge gas plenums located in between the first side and the second side, and
a plurality of purge gas riser passages, each purge gas riser passage fluidically connecting a corresponding port on the first side with one of the one or more purge gas plenums.

13. The apparatus of claim 12, wherein:
the purge gas riser passages extend through the first internal plenum volume and the second internal plenum volume, and
the purge gas riser passages are fluidically isolated from the first internal plenum volume and the second internal plenum volume.

14. (canceled)

15. (canceled)

16. The apparatus of claim 1, wherein the pedestal base further includes a deflector feature that protrudes from the first surface towards the second surface.

17. The apparatus of claim 16, wherein the deflector feature is axially symmetric about the center axis.

18. (canceled)

19. (canceled)

20. The apparatus of claim 1, wherein:
the pedestal base further includes a plurality of second vanes located within the second region, and
the second vanes extend along curved paths that spiral outward from the center axis.

21. The apparatus of claim 1, wherein:
the pedestal base further includes an inner wall that partitions the first interior plenum volume into the first region and the second region,
the coolant inlet fluidically connects with the first internal plenum volume within the second region and at a location that is radially offset from the center axis, and
the inner wall has a plurality of apertures that fluidically connect the first region with the second region within the first internal plenum volume.

22. The apparatus of claim 1, wherein:
the coolant inlet fluidically connects with the first internal plenum volume within the second region and at a location that is centered on the center axis, and
the deflector feature is centered on the center axis.

23. The apparatus of claim 1, wherein the pedestal base is made of metal and additively manufactured.

24. (canceled)

25. The apparatus of claim 1, further comprising a semiconductor processing chamber having an interior volume, wherein the pedestal base is positioned within the interior volume.
